(19) United States
(12) Patent Application Publication
(10) Pub. No.: US 2013/0139713 A1
(43) Pub. Date: Jun. 6, 2013

(54) NANO IMPRINT LITHOGRAPHY APPARATUSES AND METHODS

(71) Applicant: Samsung Electronics Co., Ltd., Suwon-Si (KR)

(72) Inventors: Young Tae CHO, Daejeon (KR); Eun Ah PARK, Yongin-si (KR); Sung Hoon LEE, Seoul (KR); Soon Won LEE, Daejeon (KR)

(73) Assignee: SAMSUNG ELECTRONICS CO., LTD., Suwon-Si (KR)

(21) Appl. No.: 13/687,585

(22) Filed: Nov. 28, 2012

(30) Foreign Application Priority Data
Dec. 6, 2011 (KR) 10-2011-0129648

(51) Int. Cl. G03F 7/00; B41K 3/00

(52) U.S. Cl. CPC G03F 7/0002; B41K 3/00
USPC 101/333; 101/450.1

(57) ABSTRACT

A nano imprint lithography apparatus includes a stamp including a main body having a first surface and a second surface, the first surface having a pattern to be imprinted on a substrate, and the second surface having at least one pole and at least one actuator configured to apply force to the at least one pole to deform the main body. The apparatus includes a stationary stage configured to support the substrate to which the pattern is transferred from the stamp. The apparatus further includes a controller configured to drive the at least one actuator to apply force to the at least one pole to deform the stamp and correct an alignment error between the stamp and the substrate.

### CROSS-REFERENCE TO RELATED APPLICATION

This application claims the benefit of Korean Patent Application No. 2011-0129648, filed on Dec. 6, 2011 in the Korean Intellectual Property Office, the disclosure of which is incorporated herein by reference.

### BACKGROUND

1. Field

At least one example embodiment relates to nano imprint lithography apparatuses and/or nano imprint lithography method.

2. Description of the Related Art

In order to process the surface of a substrate to have a desired pattern in a semiconductor fabrication process, various lithography technologies are used. Conventionally, optical lithography in which the surface of a substrate is coated with photoresist and a pattern is formed by etching the photoresist using light is generally used. However, the size of the pattern formed by optical lithography is restricted by optical diffraction and the resolution of the pattern is proportionate to the wavelength of a used ray. Therefore, as the integration density of a semiconductor element increases, an exposure technique in which light of a short wavelength is used to form a microscopic pattern is required.

As the integration density of a semiconductor element increases, the physical shape of a photoresist pattern formed through optical lithography is varied by optical interference. Particularly, non-uniform change of the critical dimension (CD) of the photoresist pattern becomes an issue. When the CD of the photoresist varies according to regions of a lower film, a pattern of a material layer formed using the photoresist pattern as a mask is distorted, and thus a realizable line width is limited. Further, the photoresist reacts with impurities generated during the process and may be eroded, and thus the photoresist pattern may be altered. Erosion of the photoresist causes the pattern of the material layer formed using the photoresist pattern as the mask to have a shape different from a desired shape.

Therefore, next generation lithography technologies through which a semiconductor integrated circuit having a nano-level line width may be formed have been investigated. These new generation lithography technologies include electron-beam lithography, ion-beam lithography, extreme ultraviolet lithography, proximity X-ray lithography and nano imprint lithography.

Nano imprint lithography involves a method in which a stamp (e.g., a mold) having a desired pattern on the surface of a material having a relatively high strength is imprinted on a substrate to transfer the pattern on the stamp to the substrate.

In nano imprint lithography, in order to transfer the pattern to a desired part of the substrate, the stamp needs to be located at the correct position on the substrate, and thus alignment of the stamp and the substrate is an important factor in determining product quality. Therefore, an improved alignment method to minimize an alignment error between the stamp and the substrate is required.

### SUMMARY

At least one example embodiment provides a nano imprint lithography apparatus having a new stamp structure.

Additional aspects of example embodiments will be set forth in part in the description which follows and, in part, will be obvious from the description, or may be learned by practice of example embodiments.

According to at least one example embodiment, a nano imprint lithography apparatus includes a stamp including a main body having a first surface and a second surface, the first surface having a pattern to be imprinted on a substrate, and the second surface having at least one pole and at least one actuator configured to apply force to the at least one pole to deform the main body. The apparatus includes a stationary stage configured to support the substrate to which the pattern is transferred from the stamp. The apparatus further includes a controller configured to drive the at least one actuator to apply force to the at least one pole to deform the stamp and correct an alignment error between the stamp and the substrate.

According to at least one example embodiment, the main body and the at least one pole include a light-transmitting material.

According to at least one example embodiment, the at least one actuator is at least one of a pneumatic type actuator, a hydraulic type actuator, a motor driving type actuator and a piezo element.

According to at least one example embodiment, the controller is configured to control the at least one actuator to generate a level of deformation of the stamp to correct the alignment error between the stamp and the substrate.

According to at least one example embodiment, a nano imprint lithography method includes loading a stamp and a substrate; performing a first alignment to adjust relative positions of the stamp and the substrate; performing a second alignment to correct an alignment error between the stamp and the substrate by applying force to at least one pole provided on a main body of the stamp so as to deform the stamp; performing at least one main process for the substrate on which the first alignment and the second alignment have been completed; and unloading the stamp and the substrate on which the main process has been completed.

According to at least one example embodiment, deformation of a pattern provided on the main body occurs simultaneously with deformation of the main body through the applying force to at least one actuator connected to the at least one pole.

According to at least one example embodiment, the alignment error is a local error caused by non-coincidence in size and shape between a part of the stamp and a corresponding part of the substrate.

According to at least one example embodiment, the alignment error is a scale error caused by non-coincidence in total size between the stamp and the substrate.

According to at least one example embodiment, the performing of the main process includes applying resist to a surface of the substrate; transferring the pattern formed on the stamp to the resist on the surface of the substrate by applying pressure to the stamp after contact of the stamp with the resist; hardening the resist; and separating the hardened resist from the substrate.

According to at least one example embodiment, the at least one actuator is separable from the at least one pole.

According to at least one example embodiment, a nano imprint lithography apparatus includes a stamp including at least one pole and at least one actuator, the at least one pole being connected to the at least one actuator, and the stamp including a pattern to be imprinted on a substrate. The apparatus further includes a controller configured to drive the at least one actuator connected to the at least one pole to deform the stamp and correct an alignment error between the stamp and the substrate.

According to at least one example embodiment, the apparatus further includes a stationary stage including one of the stamp and the substrate; and a movable stage including the other of the stamp and the substrate.

According to at least one example embodiment, the movable stage is connected to at least one position adjustment unit, the at least one position adjustment unit being configured to adjust relative positions of the stamp and the substrate in response to at least one control signal generated by the controller.

According to at least one example embodiment, the at least one pole includes a plurality of poles uniformly distributed throughout the stamp and the at least one actuator includes a plurality of actuators, each one of the plurality of actuators being connected to a corresponding one of the plurality of poles.

According to at least one example embodiment, the controller is configured to drive the plurality of actuators connected to the plurality poles to deform only a partial portion of the stamp to correct the alignment error.

According to at least one example embodiment, the partial portion of the stamp is deformed by at least one of expansion and contraction.

According to at least one example embodiment, the actuator connected to the at least one pole is configured to deform an entirety of the stamp to correct the alignment error.

According to at least one example embodiment, the entirety of the stamp is deformed by at least one of expansion and contraction.

According to at least one example embodiment, the at least one actuator is at least one of a pneumatic type actuator, a hydraulic type actuator, a motor driving type actuator and a piezo element.

According to at least one example embodiment, the at least one pole is configured to transmit light and be detachably inserted into the at least one actuator.

### BRIEF DESCRIPTION OF THE DRAWINGS

These and/or other aspects of example embodiments will become apparent and more readily appreciated from the following description of the embodiments, taken in conjunction with the accompanying drawings of which:

FIG. 1 illustrates a nano imprint lithography apparatus in accordance with at least one example embodiment;

FIGS. 2(a) to 2(c) illustrates a process of transferring a pattern of a stamp shown in FIG. 1 to a substrate;

FIGS. 3(a) and 3(b illustrates the structure of the stamp of the nano imprint lithography apparatus shown in FIG. 1;

FIG. 4 illustrates a state in which an actuator shown in FIG. 3 is driven to apply force to a pole;

FIG. 5 is a flowchart illustrating a nano imprint lithography method in accordance with at least one example embodiment;

FIGS. 6(a) to 6(c) illustrate a local alignment of a second alignment using a nano imprint lithography apparatus in accordance with at least one example embodiment;

FIGS. 7(a) to 7(c) illustrate a local alignment of a second alignment using a nano imprint lithography apparatus in accordance with at least one example embodiment;

FIGS. 8(a) to 8(c) illustrate a scale alignment of a second alignment using a nano imprint lithography apparatus in accordance with at least one example embodiment; and

FIGS. 9(a) to 9(c) illustrate a scale alignment of a second alignment using a nano imprint lithography apparatus in accordance with at least one example embodiment.

### DETAILED DESCRIPTION OF EXAMPLE EMBODIMENTS

Example embodiments will be understood more readily by reference to the following detailed description and the accompanying drawings. The example embodiments may, however, be embodied in many different forms and should not be construed as being limited to those set forth herein. Rather, these example embodiments are provided so that this disclosure will be thorough and complete. In at least some example embodiments, well-known device structures and well-known technologies will not be specifically described in order to avoid ambiguous interpretation.

It will be understood that when an element is referred to as being “connected to” or “coupled to” another element, it can be directly on, connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of the example embodiments.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises,” “comprising,” “includes,” and/or “including” when used in this specification, specify the presence of stated components, steps, operations, and/or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which these example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “below”, “beneath”, “lower”, “above”, “upper”, and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Reference will now be made in detail to example embodiments, which are illustrated in the accompanying drawings, wherein like reference numerals refer to like elements throughout.

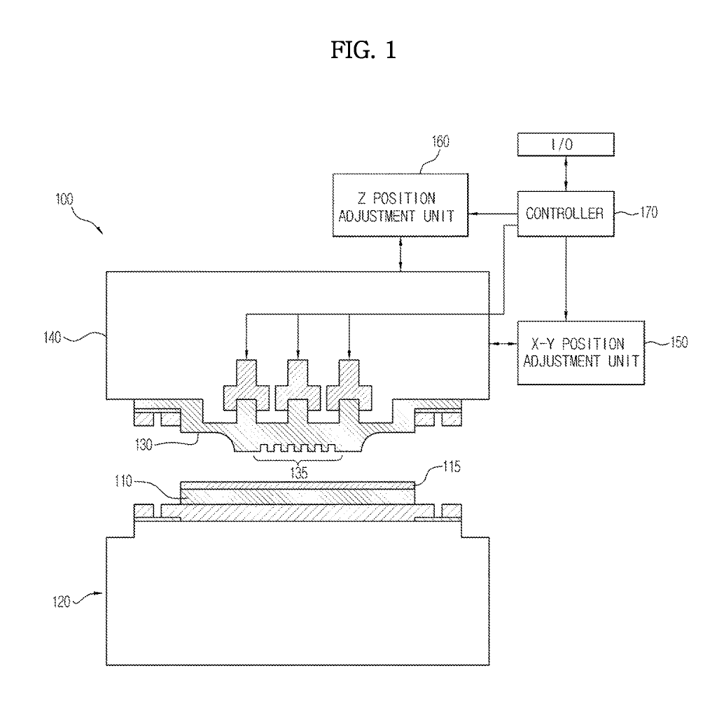

FIG. 1 illustrates a nano imprint lithography apparatus according to at least one example embodiment. As shown in FIG. 1, a nano imprint lithography apparatus 100 includes a stationary stage 120 supporting a substrate 110, a movable stage 140 supporting a stamp 130 so as to be transferable, an X-Y position adjustment unit 150 and a Z position adjustment unit 160 to adjust the position of the stamp 130, and a controller 170 controlling the overall operation of the nano imprint lithography 100.

The X-Y position adjustment unit 150 adjusts the position of the movable stage 140 on the X-Y plane by shifting the movable stage 140 in the X direction or the Y direction, and the Z position adjustment unit 160 adjusts the position of the movable stage 140 in the Z direction (i.e., a distance between the substrate 110 and the stamp 130) by shifting the movable stage 140 in the Z direction. The X-Y position adjustment unit 150 and the Z position adjustment unit 160 are operated in response to control signals from the controller 170, and thus adjust the position of the movable stage 140. Since the stamp 130 is fixed to the movable stage 140, the stamp 130 moves together with the movable stage 140. Therefore, the position of the movable stage 140 and the stamp 130 may be controlled by the controller 170.

Although FIG. 1 illustrates the substrate 110 as being supported by the stationary stage 120 and the stamp 130 as being supported by the movable stage 140 so as to be transferable, the substrate 110 may be supported by the movable stage 140 so as to be transferable and the stamp 130 may be supported by the stationary stage 120.

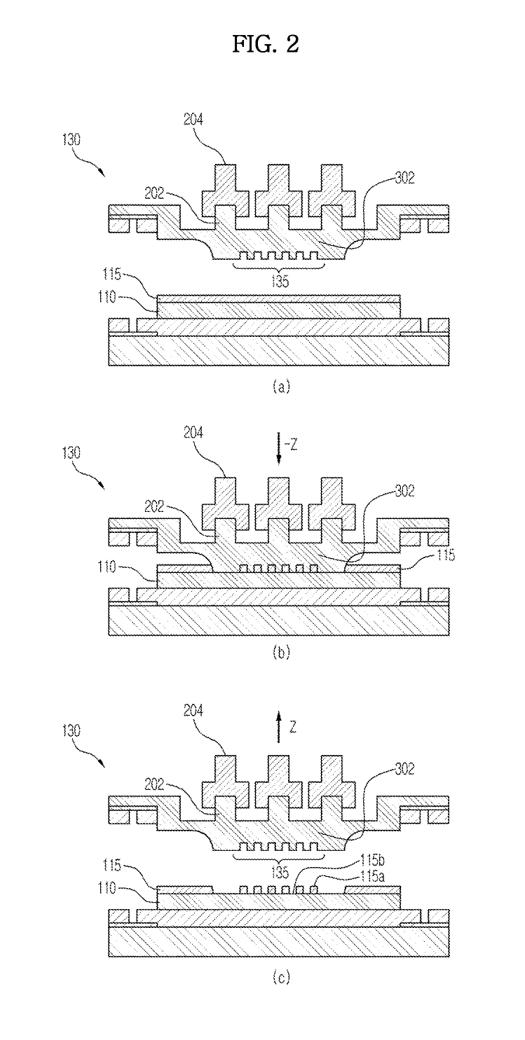

FIGS. 2(a) to 2(c) illustrate a process of transferring a pattern of the stamp shown in FIG. 1 to the substrate. In FIGS. 2(a) to 2(c), some of the elements of the nano imprint lithography apparatus 100 shown in FIG. 1 are omitted, and will thus be described with reference to FIG. 1.

As shown in FIG. 2(a), the controller 170 drives the X-Y position adjustment unit 150 to change the position of the movable stage 140 on the X-Y plane, and thus achieves a first alignment between the stamp 130 on the movable stage 140 and the substrate 110 on the stationary stage 120.

As shown in FIG. 2(b), the controller 170 drives the Z position adjustment unit 160 to transfer the movable stage 140 toward the substrate 110 in the −Z direction (in the direction shown by the arrow of FIG. 2(b)), and thus causes a pattern 135 on the stamp 130 to contact a thin film 115 and presses the pattern 135 toward the thin film 115, thereby transferring the shape of the pattern 135 to the thin film 115.

As shown in FIG. 2(c), the controller 170 drives the Z position adjustment unit 160 to transfer the movable stage 140 in the +Z direction (in the direction shown by the arrow of FIG. 2(c)), and thus separates the stamp 130 from the substrate 110, thereby separating the pattern 135 from the thin film 115.

Through the process shown in FIGS. 2(a) to 2(c), the shape of the pattern 135 including non-pressed regions 115a and pressed regions 115b is transferred to the thin film 115.

As shown in FIGS. 2(a) to 2(c), a first alignment in which relative positions of the stamp 130 and the substrate 110 are adjusted during a transfer process of nano imprint lithography is performed. Since the first alignment is a general alignment in which only the relative position of the movable stage 140 to the stationary stage 120 is adjusted by moving the entirety of the movable stage 140, a local alignment to correct an error between a part of the stamp 130 and a part of the substrate 110 may be required. That is, if there is an error between only a part of the stamp 130 and a part of the substrate 110, such a local error is not corrected even if the entirety of the stamp 130 is moved. Further, if the size of the stamp 130 is larger or smaller than the size of the substrate 110 (i.e., the scale of the stamp 130 differs from the scale of the substrate 110), a scale error is not corrected even if the entirety of the stamp 130 is moved. Alignment between the stamp 130 and the substrate 110 to correct the local error and the scale error may be referred to hereinafter as a secondary alignment. The local and/or scale error between the stamp 130 and the substrate 110 may be detected using a vision system or an optical sensor.

“Alignment” between the stamp 130 and the substrate 110 may refer to a coincidence in positions and/or sizes between the region of the pattern 135 formed on the stamp 130 and the corresponding region of the substrate 110 to which the pattern 135 will be transferred.

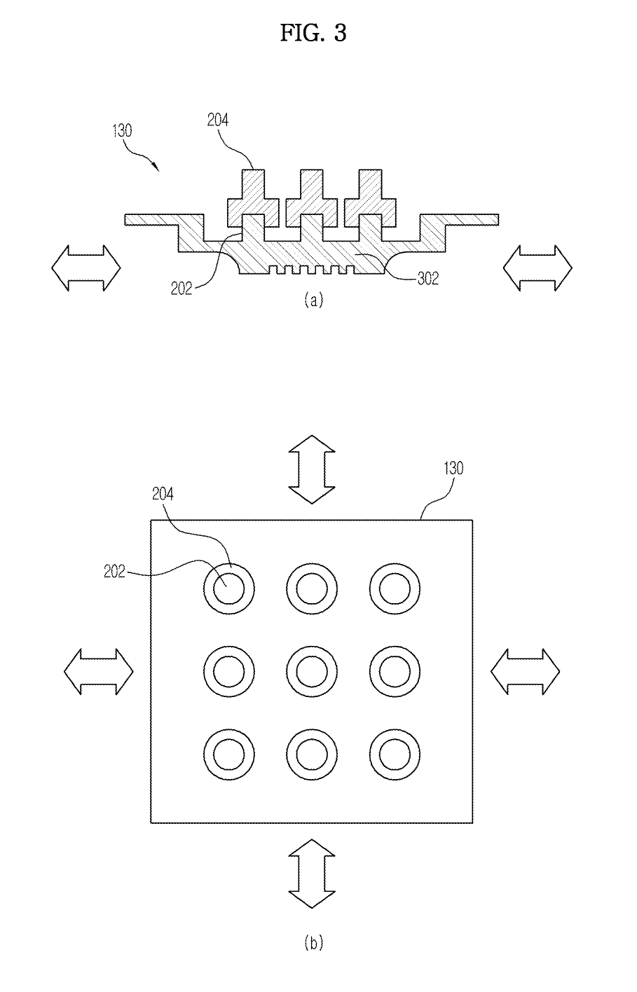

FIGS. 3(a) and 3(b) illustrate the structure of the stamp of the nano imprint lithography apparatus shown in FIG. 1. As shown in FIG. 3(a), at least one pole 202 is erected on the upper surface of a main body 302 of the stamp 130, i.e., the surface (the second surface) of the main body 302 opposite to the surface (the first surface) of the main body 302 on which the pattern 135 is formed, and an actuator 204 is connected to the pole 202. The actuator 204 serves to apply force to the pole 202, and may be one of a pneumatic type actuator, a hydraulic type actuator, a motor driving type actuator or a piezo element. The pole 202 may be formed integrally with the stamp 130, or may be separately manufactured and be attached or mechanically connected to the stamp 130. Further, the pole 202 may have a post shape or other shapes which may deform the stamp 130 by force applied through driving of the actuator 204. Further, the main body 302 and the pole 202 are formed of a light-transmitting material so as to easily transmit light, such as ultraviolet (UV) light. When force is applied to the pole 202 through driving of the actuator 204, the stamp 130 is deformed in the direction of the force applied to the pole 202, and a local error and/or a scale error between the stamp 130 and the substrate 110 may be corrected by deformation of the stamp 130. The actuator 204 may be configured to be separable from the pole 202, thereby mitigating (or alternatively, preventing) interference of light due to the actuator 204 when light, such as ultraviolet light, is irradiated during the nano imprint lithography process.

With reference to FIG. 3(b), nine poles 202 are uniformly distributed throughout the upper surface of the stamp 130 at a uniform interval. Here, the positions and the number of the poles 202 and the interval between the poles 202 may be determined according to the size and shape of the stamp 130 and the imprint shape. For example, when the size (e.g., an area) of the stamp 130 is large, the number of the poles 202 is increased, and when the size (e.g., an area) of the stamp 130 is small, the number of the poles 202 is decreased. Further, according to a desired deformation shape of the stamp 130, a smaller number of poles 202 may be installed at the center of the stamp 130 and a larger number of poles 202 may be installed at the edge of the stamp 130 so that a larger amount of deformation is generated at the edge of the stamp 130. Further still, a smaller number of poles 202 may be installed at the edge of the stamp 130 and a larger number of poles 202 may be installed at the center of the stamp 130 so that a larger amount of deformation is generated at the center of the stamp 130. In this way, the positions and the number of the poles 202 and the interval between the poles 202 are determined based on the desired deformation shape of the stamp 130, thereby deforming the stamp 130 to a desired level.

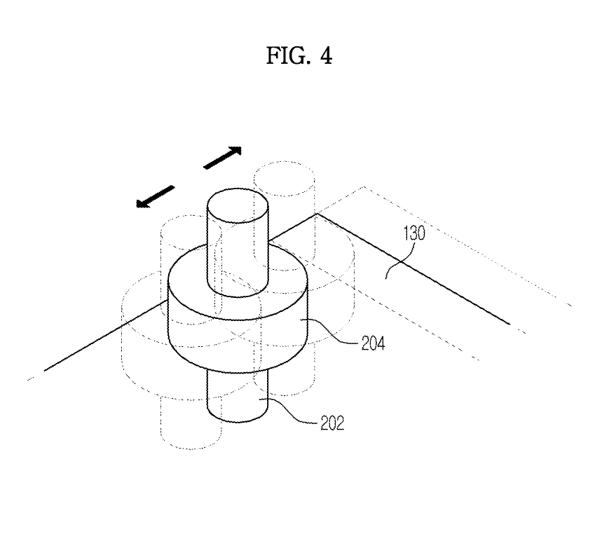

FIG. 4 is a view illustrating a state in which the actuator 204 shown in FIG. 3 is driven to apply force to the pole 202. As shown in FIG. 4, when the actuator 204 is driven to apply force to the pole 202 in a direction shown by arrows, the pole 202 expands or contracts the stamp 130 in the direction of the applied force. Here, expansion of the stamp 130 means deformation of the stamp 130 in a direction from the center of the stamp 130 to the edge of the stamp 130 so that the size (e.g., an area) of the stamp 130 increases in the corresponding direction. Contraction of the stamp 130 means deformation of the stamp 130 in a direction from the edge of the stamp 130 to the center of the stamp 130 so that the area of the stamp 130 decreases in the corresponding direction. Further, the actuator 204 may be driven to apply force to the upper surface of the stamp 130 in the Z-direction. Further, if the actuators 204 are driven to apply force to the upper surface of the stamp 130 in each direction, intensities of force applied by the respective actuators 204 may be varied. For this purpose, a force sensor (for example, a load cell) may be installed between the pole 202 and the actuator 204, and the controller 170 may receive the intensity of force detected by the force sensor through feedback. Thus, the controller 170 drives the actuator 204 to adjust the intensity of force applied to the pole 202. While the controller 170 transmits a control signal to the actuators 204, the actuators 204 transmit detection signals of the force sensors to the controller 170.

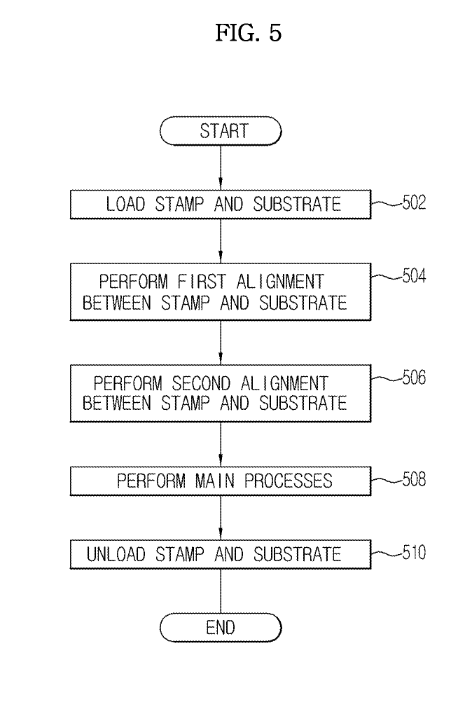

FIG. 5 is a flowchart illustrating a nano imprint lithography method in accordance with at least one example embodiment. As shown in FIG. 5, the stamp 130 and the substrate 110 are loaded (Operation 502). For example, the stamp 130 may be loaded into the movable stage 140 and the substrate 110 may be loaded into the stationary stage 120 When loading of the stamp 130 and the substrate 110 has been completed, a first alignment in which relative positions of the stamp 130 and the substrate 110 are adjusted is performed (Operation 504). In the first alignment, a relative position error between the stamp 130 and the substrate 110 is detected using a vision system or an optical sensor, and the position of the stamp 130 is adjusted to correct such an error.

When the first alignment between the stamp 130 and the substrate 110 has been completed, a secondary alignment between the stamp 130 and the substrate 110 is performed (Operation 506). The secondary alignment between the stamp 130 and the substrate 110 serves to correct a local error and/or a scale error between the stamp 130 and the substrate 110 under the condition that the relative positions of the stamp 130 and the substrate 110 are adjusted. That is, if there is a size and/or shape error between a part of the stamp 130 and a part of the substrate 110, or if there is a difference between the total sizes (i.e., scales) of the stamp 130 and the substrate 110, the stamp 130 and the substrate 110 are accurately aligned through local alignment or scale alignment. For this purpose, the shape of the stamp 130 is deformed by expanding or contracting a part or the entirety of the stamp 130 using the poles 202 and the actuators 204 in accordance with at least one example embodiment. Thereby, the local error or the scale error between the stamp 130 and the substrate 110 may be corrected. As needed, the first alignment and the second alignment may be performed together through one alignment process.

When the first alignment and the secondary alignment between the stamp 130 and the substrate 110 have been completed, one or more main process for the substrate 110 is performed (Operation 508). Here, the one or more main process may correspond to all other processes performed on the substrate 110. For example, the one or more main process may include applying resist to the surface of the substrate 110, transferring a pattern formed on the stamp 130 to the resist on the surface of the substrate 110 by applying pressure to the stamp 130 after contact of the stamp 130 with the resist, hardening the resist by applying heat or ultraviolet (UV) light to the resist, and then separating the hardened resist from the substrate 110.

When the one or more main process for the substrate 110 has been completed, the stamp 130 and the substrate 110 are unloaded (Operation 510). If there is any substrate for which processes will be performed, such a substrate is loaded and Operations 502 to 510 of FIG. 5 are repeated.

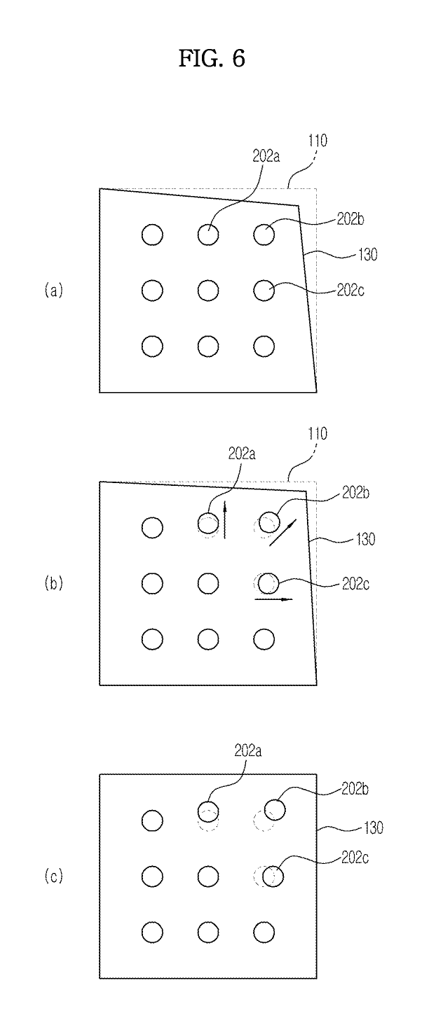

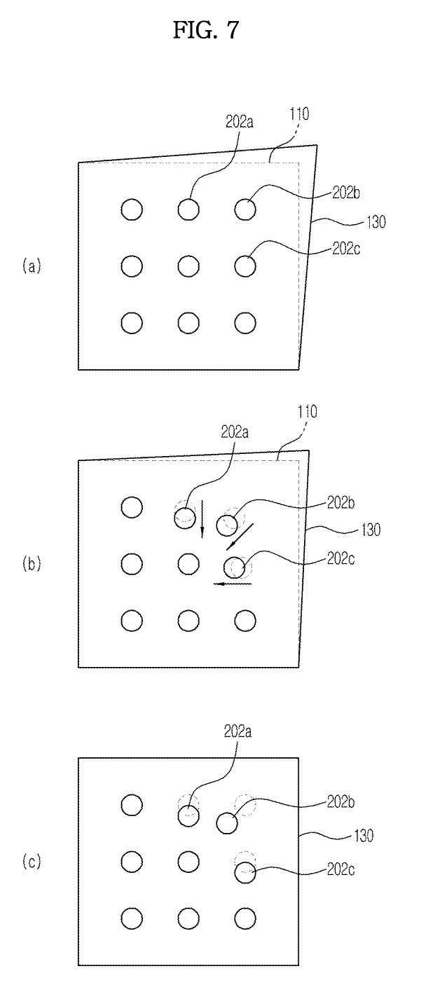

FIGS. 6(a) to 6(c) and FIGS. 7(a) to 7(c) illustrate a local alignment of a second alignment using a nano imprint lithography apparatus in accordance with at least one example embodiment. “Alignment” between the stamp 130 and the substrate 110 may refer to a coincidence in positions and/or sizes between the region of the pattern 135 formed on the stamp 130 and the corresponding region of the substrate 110 to which the pattern 135 will be transferred. Although a degree of deformation of the stamp 130 in the nano imprint lithography apparatus 10 is as small as about several tens˜hundreds of nm, FIGS. 6(a) to 6(c) and FIGS. 7(a) to 7(c) exaggerate the degree of deformation of the stamp 130 for convenience of understanding.

### One Embodiment

### Local Alignment (Expansion)

FIGS. 6(a) to 6(c) illustrate a local alignment of a second alignment using a nano imprint lithography apparatus in accordance with at least one example embodiment. FIG. 6(a) illustrates a state in which, although a first alignment (e.g., a relative position alignment) between the stamp 130 and the substrate 110 has been performed, the upper part of the right region of the stamp 130 (shown by a solid line) does not coincide with the substrate (shown by a dotted line), and thus a local alignment is required because a part of the stamp 130 is smaller than the substrate 110. In order to perform further processing on the substrate 110, the upper part of the right region of the stamp 130 needs to be expanded (e.g., extended) so as to coincide with the substrate 110 by performing a local alignment.

For this purpose, as shown in FIG. 6(b), force is applied to the three poles 202a, 202b and 202c located at the upper part of the right region of the stamp 130 in a direction shown by arrows (e.g., in a direction toward the edge of the stamp 130) so that the stamp 130 is displaced. Thereby, the stamp 130 is deformed such that the upper part of the right region of the stamp 130 is expanded (e.g., extended) in the same direction as the direction of the force applied to the three poles 202a, 202b and 202c.

Complete alignment between the substrate 110 and the stamp 130 is carried out, as shown in FIG. 6(c), by such deformation of the stamp 130. The positions of the poles 202 shown by the dotted line of FIGS. 6(b) and 6(c) are original positions of the poles 202 prior to the second alignment, and the positions of the poles 202 shown by the solid line are positions of the poles 202 changed by the second alignment.

### Another Embodiment

### Local Alignment (Contraction)

FIGS. 7(a) to 7(c) illustrate a local alignment of second alignment using a nano imprint lithography apparatus in accordance with another example embodiment. FIG. 7(a) illustrates a state in which, although a first alignment (e.g., a relative position alignment) between the stamp 130 and the substrate 110 has been performed, the upper part of the right region of the stamp 130 shown by a solid line does not coincide with the substrate shown in a dotted line, and thus a local alignment is required because a part of the stamp 130 is larger than the substrate 110. In order to perform further processing on the substrate 110, the upper part of the right region of the stamp 130 needs to be contracted (e.g., reduced) so as to coincide with the substrate 110 by performing a local alignment.

For this purpose, as shown in FIG. 7(b), force is applied to the three poles 202a, 202b and 202c located at the upper part of the right region of the stamp 130 in a direction shown by arrows (e.g., in a direction toward the center of the stamp 130) so that the stamp 130 is displaced. Thereby, the stamp 130 is deformed such that the upper part of the right region of the stamp 130 is contracted (e.g., reduced) in the same direction as the direction of the force applied to the three poles 202a, 202b and 202c.

Complete alignment between the substrate 110 and the stamp 130 is carried out, as shown in FIG. 7(c), by such deformation of the stamp 130. The positions of the poles 202 shown by the dotted line of FIGS. 7(b) and 7(c) are original positions of the poles 202 prior to the second alignment, and the positions of the poles 202 shown by the solid line are positions of the poles 202 changed by the second alignment.

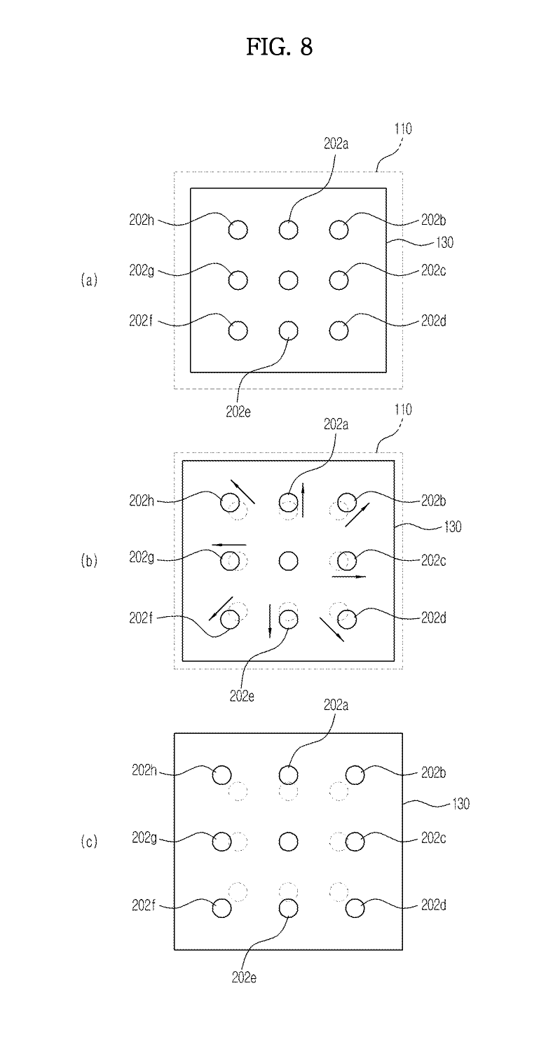

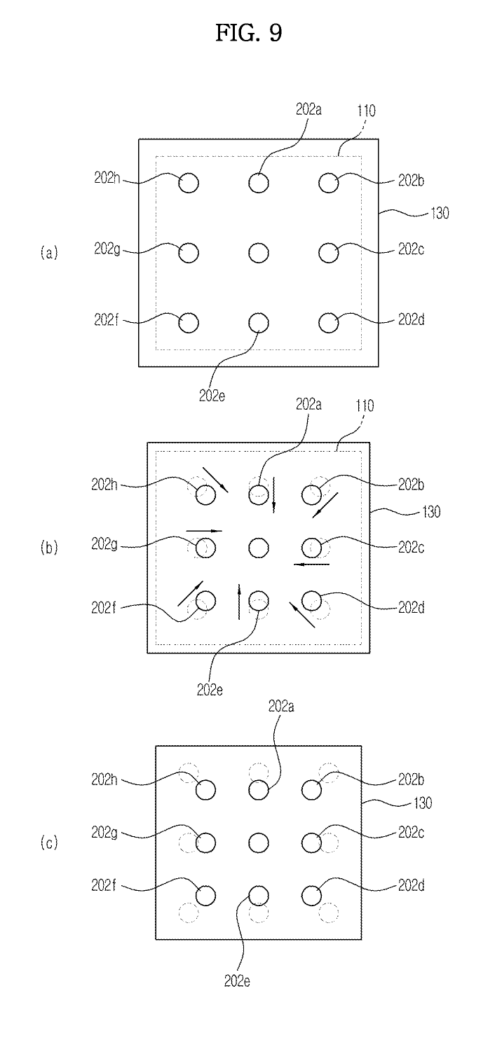

FIGS. 8(a) to 8(c) and FIGS. 9(a) to 9(c) illustrate a scale alignment of a second alignment using a nano imprint lithography apparatus in accordance with at least one example embodiment. “Alignment” between the stamp 130 and the substrate 110 may refer to a coincidence in positions and/or sizes between the region of the pattern 135 formed on the stamp 130 and the corresponding region of the substrate 110 to which the pattern 135 will be transferred. Although a degree of deformation of the stamp 130 in the nano imprint lithography apparatus 10 is as small as about several tens to about hundreds of nm, FIGS. 8(a) to 8(c) and FIGS. 9(a) to 9(c) exaggerate the degree of deformation of the stamp 130 for convenience of understanding.

### Another Embodiment

### Scale Alignment (Expansion)

FIGS. 8(a) to 8(c) illustrate a scale alignment of a second alignment using a nano imprint lithography apparatus in accordance with another example embodiment. FIG. 8(a) illustrates a state in which, although a first alignment (e.g., a relative position alignment) between the stamp 130 and the substrate 110 has been performed, the entirety of the stamp 130 shown by a solid line is smaller than the substrate 110, and thus, a size of the stamp 130 does not coincide with a size of the substrate 110. In order to perform further processing on the substrate 110, the stamp 130 needs to be expanded (e.g., extended) so as to coincide with the size of the substrate 110 by performing a scale alignment.

For this purpose, as shown in FIG. 8(b), force is applied to the eight poles 202a, 202b, 202c, 202d, 202e, 202f, 202g and 202h located at the edge of the stamp 130 in a direction shown by arrows (e.g., in a direction toward the edge of the stamp 130) so that the stamp 130 is displaced. Thereby, the stamp 130 is deformed such that the entirety of the stamp 130 is expanded (e.g., extended) in the same direction as the direction of the force applied to the eight poles 202a, 202b, 202c, 202d, 202e, 202f, 202g and 202h.

Complete alignment between the substrate 110 and the stamp 130 is carried out, as shown in FIG. 8(c), by such deformation of the stamp 130. The positions of the poles 202 shown by the dotted line of FIGS. 8(b) and 8(c) are original positions of the poles 202 prior to the second alignment, and the positions of the poles 202 shown by the solid line are positions of the poles 202 changed by the second alignment.

### Another Embodiment

### Scale Alignment (Contraction)

FIGS. 9(a) to 9(c) illustrate a scale alignment of a second alignment using a nano imprint lithography apparatus in accordance with another example embodiment. FIG. 9(a) illustrates a state in which, although a first alignment (e.g., relative position alignment) between the stamp 130 and the substrate 110 has been performed, the entirety of the stamp 130 shown by a solid line is larger than the substrate 110, and thus, a size of the stamp 130 does not coincide with a size of the substrate 110. In order to perform further processing on the substrate 110, the stamp 130 needs to be contracted (e.g., reduced) so as to coincide with the size of the substrate 110 by performing a scale alignment.

For this purpose, as shown in FIG. 9(b), force is applied to the eight poles 202a, 202b, 202c, 202d, 202e, 202f, 202g and 202h located at the edge of the stamp 130 in a direction shown by arrows (e.g., in a direction toward the center of the stamp 130) so that the stamp 130 is displaced. Thereby, the stamp 130 is deformed such that the entirety of the stamp 130 is contracted (e.g., reduced) in the same direction as the direction of the force applied to the eight poles 202a, 202b, 202c, 202d, 202e, 202f, 202g and 202h.

Complete alignment between the substrate 110 and the stamp 130 is carried out, as shown in FIG. 9(c), by such deformation of the stamp 130. The positions of the poles 202 shown by the dotted line of FIGS. 9(b) and 9(c) are original positions of the poles 202 prior to the second alignment, and the positions of the poles 202 shown by the solid line are positions of the poles 202 changed by the second alignment.

As is apparent from the above description, a nano imprint lithography apparatus in accordance with at least one example embodiment proposes a new stamp structure, and thus provides an improved alignment system which may correct a local error and/or a scale error between a stamp and a substrate.

Although example embodiments have been shown and described, it would be appreciated by those skilled in the art that changes may be made in these example embodiments without departing from the principles and spirit of the example embodiments, the scope of which is defined in the claims and their equivalents.

What is claimed is:

1. A nano imprint lithography apparatus, comprising:
a stamp including a main body having a first surface and a second surface, the first surface having a pattern to be imprinted on a substrate, and the second surface having at least one pole and at least one actuator configured to apply force to the at least one pole to deform the main body;
a stationary stage configured to support the substrate to which the pattern is transferred from the stamp; and
a controller configured to drive the at least one actuator to apply force to the at least one pole to deform the stamp and correct an alignment error between the stamp and the substrate.

2. The nano imprint lithography apparatus according to claim 1, wherein the main body and the at least one pole include a light-transmitting material.

3. The nano imprint lithography apparatus according to claim 1, wherein the at least one actuator is at least one of a pneumatic type actuator, a hydraulic type actuator, a motor driving type actuator and a piezo element.

4. The nano imprint lithography apparatus according to claim 1, wherein the controller is configured to control the at least one actuator to generate a level of deformation of the stamp to correct the alignment error between the stamp and the substrate.

5. A nano imprint lithography method, the method comprising:
loading a stamp and a substrate;
performing a first alignment to adjust relative positions of the stamp and the substrate;
performing a second alignment to correct an alignment error between the stamp and the substrate by applying force to at least one pole provided on a main body of the stamp so as to deform the stamp;
performing at least one main process for the substrate on which the first alignment and the second alignment have been completed; and
unloading the stamp and the substrate on which the main process has been completed.

6. The nano imprint lithography method according to claim 5, wherein deformation of a pattern provided on the main body occurs simultaneously with deformation of the main body through the applying force to at least one actuator connected to the at least one pole.

7. The nano imprint lithography method according to claim 5, wherein the alignment error is a local error caused by non-coincidence in size and shape between a part of the stamp and a corresponding part of the substrate.

8. The nano imprint lithography method according to claim 5, wherein the alignment error is a scale error caused by non-coincidence in total size between the stamp and the substrate.

9. The nano imprint lithography method according to claim 5, wherein the performing of the main process includes:
applying resist to a surface of the substrate;
transferring the pattern formed on the stamp to the resist on the surface of the substrate by applying pressure to the stamp after contact of the stamp with the resist;
hardening the resist; and
separating the hardened resist from the substrate.

10. The nano imprint lithography apparatus according to claim 1, wherein the at least one actuator is separable from the at least one pole.

11. A nano imprint lithography apparatus, comprising:
a stamp including at least one pole and at least one actuator, the at least one pole being connected to the at least one actuator, and the stamp including a pattern to be imprinted on a substrate; and
a controller configured to drive the at least one actuator connected to the at least one pole to deform the stamp and correct an alignment error between the stamp and the substrate.

12. The apparatus of claim 11, further comprising:
a stationary stage including one of the stamp and the substrate; and
a movable stage including the other of the stamp and the substrate.

13. The apparatus of claim 12, wherein the movable stage is connected to at least one position adjustment unit, the at least one position adjustment unit being configured to adjust relative positions of the stamp and the substrate in response to at least one control signal generated by the controller.

14. The apparatus of claim 11, wherein the at least one pole includes a plurality of poles uniformly distributed throughout the stamp and the at least one actuator includes a plurality of actuators, each one of the plurality of actuators being connected to a corresponding one of the plurality of poles.

15. The apparatus of claim 14, wherein the controller is configured to drive the plurality of actuators connected to the plurality poles to deform only a partial portion of the stamp to correct the alignment error.

16. The apparatus of claim 15, wherein the partial portion of the stamp is deformed by at least one of expansion and contraction.

17. The apparatus of claim 14, wherein the actuator connected to the at least one pole is configured to deform an entirety of the stamp to correct the alignment error.

18. The apparatus of claim 17, wherein the entirety of the stamp is deformed by at least one of expansion and contraction.

19. The apparatus of claim 11, wherein the at least one actuator is at least one of a pneumatic type actuator, a hydraulic type actuator, a motor driving type actuator and a piezo element.

20. The apparatus of claim 19, wherein the at least one pole is configured to transmit light and be detachably inserted into the at least one actuator.
